(19) United States
(12) Patent Application Publication
(10) Pub. No.: US 2021/0057663 A1
(43) Pub. Date: Feb. 25, 2021

(54) DISPLAY PANEL, MANUFACTURING METHOD THEREOF AND DISPLAY DEVICE

(71) Applicants: Beijing BOE Technology Development Co., Ltd., Beijing (CN); BOE Technology Group Co., Ltd., Beijing (CN)

(72) Inventor: Aidi ZHANG, Beijing (CN)

(21) Appl. No.: 17/051,139

(22) PCT Filed: Mar. 21, 2020
(86) PCT No.: PCT/CN2020/080530

§ 371 Date: Oct. 27, 2020

(30) Foreign Application Priority Data
May 16, 2019 (CN) 201910405243.6

(51) Int. Cl. H01L 51/50; H01L 51/56; H01L 27/32; H01L 51/52

(52) U.S. Cl. CPC H01L 51/502; H01L 51/56; H01L 51/5206; H01L 51/5072; H01L 51/5056; H01L 27/3218

(57) ABSTRACT

The disclosure provides a display panel, a manufacturing method thereof and a display device. The display panel includes a base substrate; first electrodes on the base substrate; an electron transport layer on a side of the first electrodes away from the base substrate, wherein the electron transport layer is provided with a plurality of pore structures; quantum dot light emitting layers on the side of the electron transport layer away from the base substrate, wherein the electron transport layer is in direct contact with the quantum dot light emitting layers; and a second electrode on the side of the quantum dot light emitting layers away from the base substrate.

### CROSS-REFERENCE TO RELATED APPLICATIONS

The disclosure is a US National Stage of International Application No. PCT/CN2020/080530, filed Mar. 21, 2020, which claims priority to Chinese Patent Application No. 201910405243.6, filed with Chinese Patent Office on May 16, 2019, and entitled “Quantum Dot Electroluminescent Diode, Display Panel and Manufacturing Method”, which is hereby incorporated by reference in its entirety.

### FIELD

The disclosure relates to the technical field of light emitting devices, in particular to a display panel, a manufacturing method thereof and a display device.

### BACKGROUND

Quantum dot (QD) materials are novel light emitting materials and have the advantages of narrow light emitting spectrum, adjustable light emitting wavelength, high spectral purity and the like, and a quantum dot light emitting diode (QLED) device with the quantum dot materials as a light emitting layer becomes the main research direction of novel display devices at present.

In order to realize a full-color quantum dot light emitting diode device, quantum dot light emitting layer needs to be patterned, because an electron transport layer is loose, particles in the electron transport layer are likely to fall off in a patterning process, thus the quantum dot light emitting layer is also likely to fall off; and even if an electron transport layer with a compact structure may be obtained through some processes, the contact area between the electron transport layer and quantum dots of the quantum dot light emitting layer is relatively small, so that few quantum dots can be bound, and the light emitting effect of the quantum dot light emitting layers is influenced.

### SUMMARY

An embodiment of the disclosure provides a display panel, including: a base substrate; first electrodes on the base substrate; an electron transport layer on a side of the first electrodes away from the base substrate; wherein the electron transport layer is provided with a plurality of pore structures; quantum dot light emitting layers on the side of the electron transport layer away from the base substrate, wherein the electron transport layer is in direct contact with the quantum dot light emitting layers; and a second electrode on a side of the quantum dot light emitting layers away from the base substrate.

Optionally, in the embodiment of the disclosure, the diameters of the pore structures of the electron transport layer are within a range [5 nm, 100 nm].

Optionally, in the embodiment of the disclosure, the material of the electron transport layer includes metallic oxide.

Optionally, in the embodiment of the disclosure, the surface of the electron transport layer is provided with a hydrophilic ligand.

Optionally, in the embodiment of the disclosure, the display panel further includes a hole transport layer between the quantum dot light emitting layers and the second electrode, and a hole injection layer between the hole transport layer and the second electrode.

Correspondingly, an embodiment of the disclosure further provides a display device, including the display panel.

Correspondingly, an embodiment of the disclosure further provides a manufacturing method of the display panel. The manufacturing method includes: forming first electrodes on a base substrate; forming an electron transport layer with a plurality of pore structures on the first electrodes; forming quantum dot light emitting layers on the electron transport layer, wherein the electron transport layer is in direct contact with the quantum dot light emitting layers; and forming a second electrode on the quantum dot light emitting layers.

Optionally, in the embodiment of the disclosure, the forming the electron transport layer with the plurality of pore structures on the first electrodes includes: preparing a zinc precursor solution by using a compound containing zinc ions; forming a thin film on the first electrodes by using the zinc precursor solution; and heating the display panel to enable the compound containing the zinc ions in the zinc precursor solution to be decomposed to generate gas and form the electron transport layer with the plurality of pore structures.

Optionally, in the embodiment of the disclosure, the preparing the zinc precursor solution by using the compound containing the zinc ions includes: preparing a mixed solution of a dispersant and an organic solvent, wherein the boiling point of the dispersant is different from the boiling point of the organic solvent; adding the compound containing the zinc ions to the mixed solution; and heating and stirring the mixed solution with the compound containing the zinc ions to form the zinc precursor solution.

Optionally, in the embodiment of the disclosure, the amount of the dispersant is within a range [1 ml, 8 ml].

Optionally, in the embodiment of the disclosure, the heating the display panel includes: heating the display panel in an environment in a first temperature range for a first duration; wherein the first temperature range is [80° C., 150° C.], and the first duration is within a range [5 min, 10 min].

Optionally, in the embodiment of the disclosure, the heating the display panel includes: heating the display panel for [5 min, 7 min] in a temperature range [80° C., 100° C.]; and heating the display panel for [8 min, 10 min] in a temperature range [120° C., 150° C.].

Optionally, in the embodiment of the disclosure, after heating the display panel in the environment in the first temperature range for the first duration, the manufacturing method further includes: heating the display panel in an environment in a second temperature range for a second duration; wherein the second temperature range is [200° C., 300° C.], and the second duration is in a range [3 min, 10 min].

Optionally, in the embodiment of the disclosure, after heating the display panel, the manufacturing method further includes: coating an aqueous solution containing a binder on the surface of the electron transport layer; and heating the display panel in a third temperature range for a third duration to obtain the electron transport layer of which the surface is provided with a hydrophilic ligand.

Optionally, in the embodiment of the disclosure, the display panel includes sub-pixels in at least three colors; the forming the quantum dot light emitting layers on the electron transport layer includes: forming the quantum dot light emitting layers in corresponding colors respectively in sub-pixel regions in different colors; wherein for the sub-pixel regions in each color, the forming the quantum dot light emitting layers in the corresponding color includes: coating a photoresist layer on the electron transport layer, and patterning the photoresist layer to remove the photoresist layer in the sub-pixel regions in the corresponding color; spin-coating quantum dot materials in the corresponding color on the whole surface of the photoresist layer; and stripping off the photoresist layer to remove the quantum dot materials on the photoresist layer, and forming the quantum dot light emitting layers in the sub-pixel regions in the color.

Optionally, in the embodiment of the disclosure, after forming the quantum dot light emitting layers on the electron transport layer and before forming the second electrode on the quantum dot light emitting layers, the manufacturing method further includes: forming a hole transport layer on the quantum dot light emitting layers; and forming a hole injection layer on the hole transport layer.

### BRIEF DESCRIPTION OF THE DRAWINGS

FIG. 1 is a scanning electron microscope diagram of a compact zinc oxide thin film in related art;

FIG. 2 is a schematic structural diagram of a display panel according to an embodiment of the disclosure;

FIG. 3 is a scanning electron microscope diagram of an electron transport layer according to an embodiment of the disclosure;

FIG. 4 is a high-resolution scanning electron microscope diagram of the electron transport layer according to an embodiment of the disclosure;

FIG. 5 is a flow diagram of a manufacturing method of the display panel according to an embodiment of the disclosure;

FIG. 6 is a flow diagram of a manufacturing method of quantum dot light emitting layers in each color according to an embodiment of the disclosure;

FIG. 7 is a flow diagram of manufacturing of red quantum dot light emitting layers in red sub-pixel regions according to an embodiment of the disclosure;

FIG. 8 is a schematic structural diagram of forming of the red quantum dot light emitting layers in the red sub-pixel regions according to an embodiment of the disclosure;

FIG. 9 is a flow diagram of forming of red quantum dot light emitting layers in red sub-pixel regions in related art;

FIG. 10 is a flow diagram of forming of green quantum dot light emitting layers in green sub-pixel regions according to an embodiment of the disclosure;

FIG. 11 is a schematic structural diagram of green quantum dot light emitting layers in the green sub-pixel regions according to an embodiment of the disclosure;

FIG. 12 is a flow diagram of forming of blue quantum dot light emitting layers in blue sub-pixel regions according to an embodiment of the disclosure; and

FIG. 13 is a schematic structural diagram of forming of the blue quantum dot light emitting layers in the blue sub-pixel regions according to an embodiment of the disclosure.

### DETAILED DESCRIPTION

In order to realize a full-color quantum dot light emitting diode device, quantum dot light emitting layers in different colors need to be introduced into pixels, so that the quantum dot light emitting layers need to be patterned, the patterned quantum dot light emitting layers may be prepared by adopting a photolithography process, however, an electron transport layer is generally made of a zinc oxide material and the film structure thereof is relatively loose, and when the quantum dot light emitting layers are patterned, particles in the electron transport layer are likely to wash away by a developing solution, so that the quantum dot light emitting layers on the electron transport layer also fall off.

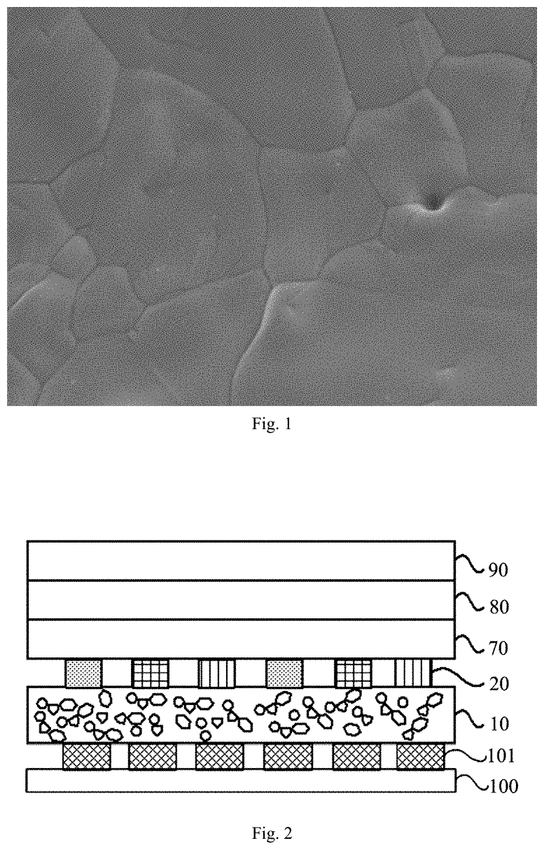

In order to prevent zinc oxide particles in the electron transport layer from falling off, a compact zinc oxide thin film may be prepared by adopting a sol-gel method to obtain the electron transport layer. FIG. 1 is a scanning electron microscope diagram of the compact zinc oxide thin film, and the structure of the zinc oxide thin film is relatively compact as can be seen from FIG. 1. The surface area of the electron transport layer is relatively fixed, and the contact area between the electron transport layer and quantum dots of the light emitting layer is relatively small, so that few quantum dots can be bound, and the light emitting effect of the light emitting layer is likely to be influenced.

In view of this, an embodiment of the present disclosure provides a display panel, a manufacturing method thereof and a display device. The implementations of the display panel, the manufacturing method thereof and the display device provided by the embodiment of the present disclosure are described in detail below in combination with attached drawings. The thickness and shape of various film layers in the attached drawings do not reflect true proportions and are merely illustrative of the disclosure.

An embodiment of the present disclosure provides a display panel. Referring to FIG. 2, the display panel includes: a base substrate 100; first electrodes 101 on the base substrate 100; an electron transport layer 10 on a side of the first electrodes 101 away from the base substrate 100, wherein the electron transport layer 10 is provided with a plurality of pore structures; quantum dot light emitting layers 20 on the side of the electron transport layer 10 away from the substrate 100, wherein the electron transport layer 10 is in direct contact with the quantum dot light emitting layers 20; and a second electrode 90 on a side of the quantum dot light emitting layers 20 away from the substrate 100.

In the display panel according to the embodiment of the disclosure, the electron transport layer is provided with a plurality of pore structures, the specific surface area of the electron transport layer may be increased, and the electron transport layer is not likely to fall off when the quantum dot light emitting layers are patterned, so that the quantum dot light emitting layers on the electron transport layer are not likely to fall off; and therefore, when the quantum dot light emitting layers are patterned, the yield of quantum dots is improved. Moreover, the electron transport layer is in direct contact with the quantum dot light emitting layers, so that the contact area between quantum dots in the quantum dot light emitting layers and the electron transport layer may be increased, more quantum dots are bound by the electron transport layer, and the light emitting effect of the quantum dot light emitting layers is improved.

Since the electron transport layer 10 is provided with the pore structures, when the electron transport layer 10 is in direct contact with the quantum dot light emitting layers 20, the quantum dots in the quantum dot light emitting layers 20 are in contact with the surface of the electron transport layer 10, and further are in contact with the inner surfaces of the pore structures in the electron transport layer 10, thus the contact area between the quantum dots in the quantum dot light emitting layers 20 and the electron transport layer 10 is increased, more quantum dots may be bound and confined, and the light emitting effect of the quantum dot light emitting layers 20 is enhanced.

In one possible implementation, in the display panel according to the embodiment of the disclosure, the material of the electron transport layer 10 may include a metallic oxide, such as zinc oxide. The electron transport layer 10 is provided with the pore structures, so that the electron transport layer 10 has relatively high specific surface area, thus the contact rate between the electron transport layer 10 and the quantum dot light emitting layer 20 may be improved, effective injection of electrons from the electron transport layer 10 to the quantum dot light emitting layers 20 may be better achieved, and when the quantum dot light emitting layers 20 on the electron transport layer 10 are patterned through the photolithography process, the quantum dot light emitting layers 20 are not likely to fall off.

In some implementations, in the display panel according to the embodiment of the disclosure, the diameter of the pore structures of the electron transport layer 10 is within a range [5 nm, 100 nm].

If the pore structures of the electron transport layer 10 are large, the structure of the electron transport layer 10 is relatively loose, the electron transport layer 10 is likely to be washed away by a developing solution, and if the pore structures of the electron transport layer 10 are smaller, the specific surface area of the electron transport layer 10 is larger, and the contact area between the electron transport layer 10 and the quantum dot light emitting layer 20 is larger, so that more quantum dots may be adsorbed. Therefore, the diameter of the pore structures in the electron transport layer 10 in the embodiment of the disclosure is within the range [5 nm, 100 nm], and while the structure of the electron transport layer 10 is compact, more quantum dots can be adsorbed.

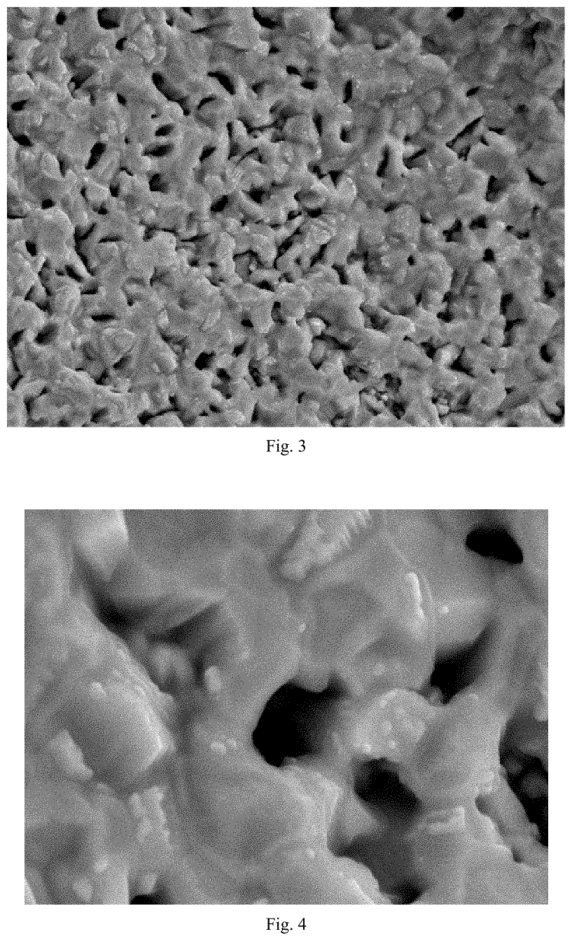

FIG. 3 is a scanning electron microscope diagram of the electron transport layer according to an embodiment of the disclosure. FIG. 4 is a high-resolution scanning electron microscope diagram of the electron transport layer according to an embodiment of the disclosure. As can be seen in FIG. 3 and FIG. 4, the electron transport layer 10 according to the embodiment of the disclosure is provided with pore structures relative to the electron transport layer 10 shown in FIG. 1.

In practical application, in the display panel according to the embodiment of the disclosure, the surface of the electron transport layer is provided with a hydrophilic ligand.

The hydrophilic ligand has a modification effect on the electron transport layer, so that connection between the hydrophilic electron transport layer and the hydrophobic quantum dot light emitting layer may be enhanced, and the quantum dot light emitting layer further prevented from falling off or being damaged in a developing process.

Specifically, the surface of the electron transport layer is coated with an aqueous solution containing a binder and then is heated to form a hydrophilic ligand on the surface of the electron transport layer. Specifically, the binder may be a compound containing a specific chemical functional group, such as a compound containing an amino and a sulfydryl, and cysteine, the amino of the cysteine and hydroxyl on the surface of the electron transport layer 10 may be subjected to oxyamination reaction, the sulfydryl of the cysteine is a good ligand for quantum dots and may serve as a ligand of the quantum dots to passivate the quantum dots, and therefore, the quantum dot light emitting layers 20 are not likely to be washed away or damaged by the developing solution. In addition, the binder may also be other small molecule compositions, and the material of the binder is not limited here.

Specifically, in the display panel according to the embodiment of the disclosure, as shown in FIG. 2, the display panel may further include a hole transport layer 70 between the quantum dot light emitting layers 20 and the second electrode 90, and a hole injection layer 80 between the hole transport layer 70 and the second electrode 90.

Through the hole injection layer 80 and the hole transport layer 70, carriers in the second electrode 90 may be injected and transported to the quantum dot light emitting layer 20 to realize light emission of quantum dots.

Based on the same inventive concept, an embodiment of the disclosure further provides a display device which includes the display panel above. The display device may be applied to any product or component with a display function, such as a mobile phone, a tablet computer, a television, a display, a notebook computer, a digital photo frame and a navigator. The principle for solving the problem of the display device is similar to that of the display panel, so that implementation of the display device may refer to implementation of the display panel, and repeated description is omitted here.

Based on the same inventive concept, an embodiment of the disclosure further provides a manufacturing method of the display panel, and the principle of the manufacturing method for solving the problem is similar to that of the display panel, so that implementation of the manufacturing method may refer to implementation of the display panel, and repeated description is omitted here.

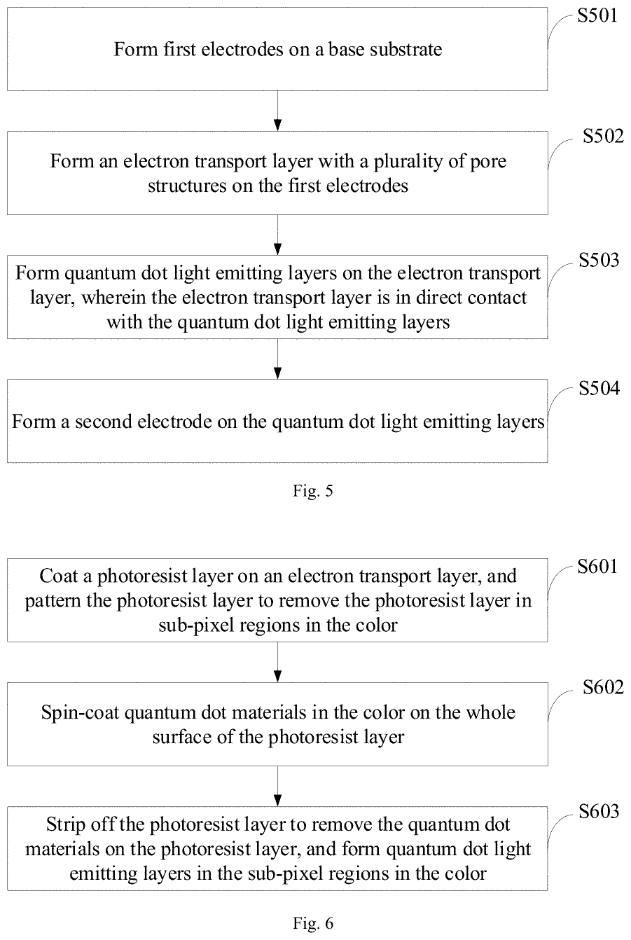

An embodiment of the present disclosure further provides a manufacturing method of the display panel, Referring to FIG. 5 and FIG. 2, and the flow of the manufacturing method is described as follows.

S501: first electrodes 101 are formed on a base substrate 100.

S502: an electron transport layer 10 with a plurality of pore structures is formed on the first electrodes 101.

S503: quantum dot light emitting layers 20 are formed on the electron transport layer 10, wherein the electron transport layer 10 is in direct contact with the quantum dot light emitting layers 20.

S504: a second electrode 90 is formed on the quantum dot light emitting layers 20.

In the manufacturing method according to the embodiment of the disclosure, the electron transport layer are formed with the plurality of pore structures, thus the specific surface area of the electron transport layer may be increased, the contact area between the quantum dot light emitting layers and the electron transport layer is increased, the quantum dot light emitting layers are prevented from falling off in a patterning process. Moreover, more quantum dots are bound by the electron transport layer, so that the light emitting effect of the quantum dot light emitting layers is improved.

Optionally, in the step S501, the material of the first electrodes 101 may be indium tin oxide (ITO) or FTO glass, wherein FTO is fluorine-doped SnO₂ conductive glass (SnO₂:F).

Specifically, in the manufacturing method according to the embodiment of the disclosure, the step S502 may include (not shown in figures) the following steps.

S5021: a zinc precursor solution is prepared by using a compound containing zinc ions.

S5022: a thin film is formed on the first electrodes by using the zinc precursor solution.

S5023: the display panel is heated, so that the compound containing the zinc ions in the zinc precursor solution is decomposed to generate gas, to form the electron transport layer with the plurality of pore structures.

Specifically, taking zinc oxide as the material of the electron transport layer 10 as an example, in the step S5021, the compound containing the zinc ions may be, for example, zinc nitrate, zinc acetate, or zinc sulfate, or may be an organic zinc compound such as zinc isoocatanoate, zinc naphthenate, dimethylzinc and dibutylzinc laurate.

In implementation, in the manufacturing method according to the embodiment of the disclosure, the step S5021 may include: preparing a mixed solution of a dispersant and an organic solvent, wherein the boiling point of the dispersant is different from that of the organic solvent; adding the compound containing the zinc ions to the mixed solution of the dispersant and the organic solvent; and heating and stirring the mixed solution with the compound containing the zinc ions, to form the zinc precursor solution.

During implementation, the dispersant can enable zinc ions in the zinc precursor solution to be more uniform, specifically, the dispersant may be ethylene glycol monomethyl ether, and the organic solvent may be n-butanol. Of course, the mixed solution is by way of example only. In another embodiment, a mixed solvent of ethylene glycol monomethyl ether and n-butanol may be replaced with another mixed solution. For example, the dispersant may be another material which burns in air, has an ignition point below 200° C. and is miscible with alcohol solvents such as n-butanol, and for example, the dispersant may be a functional group compound containing hydroxyl and an ether bond such as diethylene glycol monomethyl ether. For example, the organic solvent may be a low boiling point solvent containing hydroxyl such as glycerol, isopropanol, t-butanol and isobutanol, and the low boiling point refers to a boiling point less than 200° C.

In a possible implementation, the amount of the dispersant is within a range [1 ml, 8 ml].

Different relative amounts of the dispersant and the compound containing the zinc ions in the zinc precursor solution may result in different pore diameters of the pore structures of the electron transport layer 10. Therefore, according to the embodiment of the disclosure, the relative amounts of the dispersant and the compound containing the zinc ions in a zinc precursor solution may be adjusted, so that the contact area between the electron transport layer 10 and the quantum dot light emitting layer 20 is as large as possible.

For example, when the compound containing the zinc ions is 4.5 g of zinc nitrate hexahydrate and the amount of the dispersant is 6 ml, the formed electron transport layer 10 has a large number of pores, the pores are small, and in this way, the contact area between the electron transport layer 10 and the quantum dot light emitting layer 20 is large, so that more quantum dots may be bound, that is, the probability that the quantum dots in the sub-pixel regions are washed away is lower, the breakage rate of the quantum dots in the sub-pixel regions is minimum, and the breakage rate may be understood as the proportion of the broken quantum dots in the sub-pixel regions in one hundred of any continuous sub-pixel regions.

In the step S5022, a thin film is formed on the first electrodes by using the obtained zinc precursor solution. For example, the zinc precursor solution is dropwise added to a layer of the first electrodes, and a thin film may be formed by spin-coating.

In the step S5023, the display panel is heated, the dispersant in the zinc precursor solution burns, thus the compound containing the zinc ions in the zinc precursor solution is decomposed to generate gases, and meanwhile, an organic solvent is removed by heating to form a zinc oxide thin film with pore structures. Specifically, the chemical equation of the zinc oxide thin film with the pore structures is as follows:

Zn(NO₃)₂+C₃H₈O₂+O₂→ZnO+CO₂(gas)+H₂O(gas)+Na(gas)

As can be seen from the chemical equation, the dispersant in the zinc precursor solution burns to generate gases such as CO₂, H₂O and Na, so that the formed electron transport layer has a plurality of pore structures.

Due to the fact that the boiling points of the dispersant and the organic solvent in the mixed solution are different, the volatilization rates of the dispersant and the organic solvent are different in the heating process of the mixed solution, it can be guaranteed that bubbles generated in the zinc precursor solution are continuously volatilized within different time, and then an electron transport layer with a multi-layered structure may be obtained.

In the step S5023, the pore diameters of the pore structures of the formed electron transport layer 10 are different under different heating temperatures and different heating durations in the process of heating the display panel, so that the heating temperature and/or the heating duration of the display panel may be adjusted when the electron transport layer 10 is manufactured in the embodiment of the disclosure, then the generation rate and the generation amount of the gases in the reaction are further controlled, and the pore diameters of the obtained pore structures can meet actual requirements.

In a possible implementation, in the manufacturing method according to the embodiment of the disclosure, and the step S5023 of heating the display panel includes: heating the display panel in an environment in a first temperature range for a first duration, wherein the first temperature range is [80° C., 150° C.], and the first duration is within the range [5 min, 10 min].

In an implementation, the display panel may be subjected to heating process one time, or may be subjected to heating process for multiple times, thus, processes of generating gases in the heating process may be separate, and the finally obtained electron transport layer has the stereoscopic and multi-layered pore structures.

Specifically, in the manufacturing method according to the embodiment of the disclosure, the step S5023 of heating the display panel include: heating the display panel in a temperature range [80° C., 100° C.] for [5 min, 7 min], so that the dispersant in the zinc precursor solution burns, and the compound containing the zinc ions is decomposed to generate a small amount of gas which is released slowly; and then heating the display panel in a temperature range [120° C., 150° C.] for [8 min, 10 min], at this time, the compound containing the zinc ions is decomposed to generate a large amount of gas which is released rapidly, and thus, the compact and continuous electron transport layer with micro-scale and nano-scale layered pore structures may be formed finally.

Further, in the display panel according to the embodiment of the disclosure, after the step that the display panel is placed in the environment in the first temperature range for the first duration, the following step may further be performed.

The display panel is heated in an environment in a second temperature range for a second duration to form the electron transport layer; wherein the second temperature range is [200° C., 300° C.], and the second duration is within a range [3 min, 10 min].

After the display panel is heated for the first duration, the display panel is continuously heated for a second duration, the crystallinity of the electron transport layer may be improved, and thus the electron transport property of the electron transport layer is improved.

In order to facilitate understanding, the following introduces, by way of examples, how to form the electron transport layer with the pore structures.

(1) The zinc precursor solution is prepared.

4.5 g of solid zinc nitrate hexahydrate is added to a beaker containing 10 mL of a mixed solution of ethylene glycol monomethyl ether and n-butanol, and the mixture is stirred at the temperature of 30-60° C. for 1-2 h to obtain a zinc precursor solution.

(2) The electron transport layer with the pore structures is prepared.

100 μL-200 μL of the zinc precursor solution is dropwise added onto a layer of the first electrodes and then spin-coated to form a thin film, and the glass is placed on a heating table, and is heated at the temperature of 80° C.-150° C. for 5 min-10 min firstly. In the heating process, the ethylene glycol monomethyl ether and the like in the zinc precursor solution burn, and then zinc nitrate is oxidized and decomposed. In the reaction process, a large amount of gases (CO₂, H₂O and the like) may be generated, and the gases are released to form the electron transport layer with the pore structures. Then the temperature is continued to be increased to 200° C.-300° C. so as to improve the crystallinity of the electron transport layer.

In the embodiment of the disclosure, when the electron transport layer is manufactured, the heating temperature and/or the heating rate of the display panel may also be adjusted, so that the gas generation rate and the gas generation amount in the reaction are controlled to obtain the electron transport layer with the pore diameters of the pore structures meeting actual requirements.

For example, in the embodiment of the disclosure, 4.5 g of solid zinc nitrate hexahydrate may be added to a mixed solution containing 10 mL of ethylene glycol monomethyl ether and n-butanol to prepare a zinc precursor solution. 100 μL of the zinc precursor solution is spin-coated on conductive glass to form a film. The conductive glass is placed on the heating table, the temperature is controlled to rise from room temperature 25° C. to 300° C., and the heating rates are set to be 5° C./min and 10° C./min, respectively. When the heating rate is 5° C./min, generated bubbles are 50 μL/min. When the heating rate is 10° C./min, generated bubbles are 80 μL/min. Therefore, in the embodiment of the disclosure, the generation rate of the bubbles may be controlled by controlling the heating rate, so that the pore diameters of the pore structures in the electron transport layer are controlled.

In practical application, in the manufacturing method according to the embodiment of the disclosure, after the step S5023, the following steps may further be performed. The surface of the electron transport layer is coated with an aqueous solution containing a binder. The display panel is heated in a third temperature range for a third duration to obtain the electron transport layer of which the surface is provided with a hydrophilic ligand.

The hydrophilic ligand has a modification effect on the electron transport layer, so that connection between the hydrophilic electron transport layer and the hydrophobic quantum dot light emitting layer may be enhanced, and the quantum dot light emitting layer is further prevented from falling off or being damaged in the developing process.

Specifically, the surface of the electron transport layer is coated with the aqueous solution containing the binder, and then a hydrophilic ligand is formed on the surface of the electron transport layer after heating. Specifically, the binder may be a compound containing a specific chemical functional group to obtain the electron transport layer containing the hydrophilic ligand (such as hydroxyl) so as to further increase the contact area between the electron transport layer and the quantum dot light emitting layer.

In implementation, the binder may be formed by adopting a small molecule composition, for example, the material of the binder may be a compound containing amino and sulfydryl, such as cysteine, the amino of the cysteine and the hydroxyl on the surface of the electron transport layer may be subjected to oxyamination reaction, the sulfydryl of the cysteine is a good ligand for the quantum dots, and may serve as a ligand of the quantum dots to passivate the quantum dots, so that the quantum dot light emitting layer is not likely to be washed away or damaged by a developing solution, and the contact area between the electron transport layer and the quantum dot light emitting layers is further increased.

Specifically, a layer of aqueous solution with cysteine may coat the surface of the electron transport layer, and the substrate is placed in an environment at the temperature of 40° C.-60° C. and heated for 10-30 minutes to form a hydrophilic ligand on the surface of the electron transport layer.

In practical application, in order to realize full-color picture display, the display panel includes sub-pixels in at least three colors. For example, the display panel may include red sub-pixels, blue sub-pixels and green sub-pixels; and in the step S502, by forming the electron transport layer with the pore structures, the contact area between the quantum dot light emitting layer to be formed and the electron transport layer may be increased, so that a stable foundation is provided for subsequent patterning of the quantum dot light emitting layers.

The step S503 may include: forming quantum dot light emitting layers in corresponding colors in sub-pixel regions in different colors.

Specifically, referring to FIG. 6, the quantum dot light emitting layers in the corresponding color are formed in the sub-pixel regions in each color, and the specific flow is described as follows.

S601: coating a photoresist layer on the electron transport layer, and patterning the photoresist layer to remove the photoresist layer in the sub-pixel regions in the color.

S602: spin-coating the quantum dot materials in the color on the whole surface of the photoresist layer.

S603: stripping off the photoresist layer to remove the quantum dot materials on the photoresist layer, and forming the quantum dot light emitting layers in the sub-pixel regions in the color.

Specifically, in the step S601, the photoresist layer may coat the electron transport layer by spin-coating, and then the photoresist layer is patterned by exposure and development process so as to remove the photoresist layer in the sub-pixel regions in the color.

In the step S602, the quantum dot materials in the color may coat the whole surface of the photoresist layer in a spin-coating manner.

In the step S603, the display panel is full exposed, then is subjected to a developing process to remove the remaining photoresist layer in the display panel, and the quantum dot materials outside the sub-pixel regions in the color are also removed, so that quantum dot light emitting layers are formed in the sub-pixel regions in the color.

In the embodiment of the disclosure, the sequence of forming the quantum dot light emitting layers in the sub-pixel regions in different colors is not limited. In order to facilitate understanding, manufacturing of quantum dot light emitting layers in red sub-pixel regions is taken as an example firstly to introduce how to form quantum dot light emitting layers in corresponding colors in sub-pixel regions in different colors.

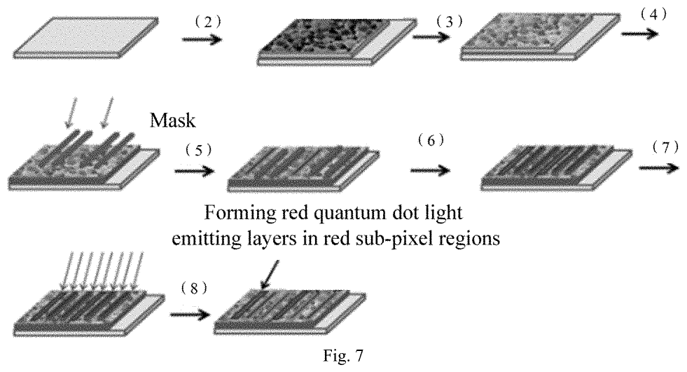

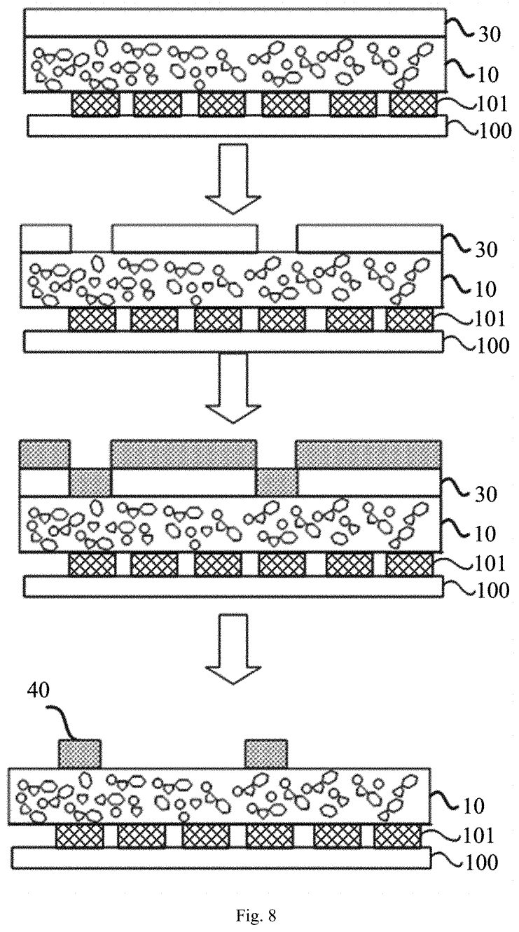

FIG. 7 is a flow diagram of forming red quantum dot light emitting layers in red sub-pixel regions, FIG. 8 is a corresponding structural diagram of forming the red quantum dot light emitting layers in the red sub-pixel regions. As shown in FIG. 7 and FIG. 8, forming of the red quantum dot light emitting layers in the red sub-pixel regions includes the following steps.

(1) First electrodes 101 are formed on a base substrate 100, for example, the first electrodes 101 are formed by indium tin oxide material, and the display panel is cleaned after the first electrodes 101 are formed, for example, the display panel is cleaned by adopting isopropanol, water or acetone in an ultrasonic manner, and the display panel is subjected to ultraviolet irradiation treatment for 5-10 minutes to eliminate dust and organic matters on the surface of the display panel.

(2) An electron transport layer 10 with pore structures is formed on a layer of the first electrodes 101. Specifically, 1000 μL-300 μL of a zinc precursor solution coats on the layer of the first electrodes 101. The display panel is heated on a heating table at the temperature of 80° C.-150° C. to form the electron transport layer 10.

(3) A photoresist layer 30 (which may be, for example, a positive photoresist) coats on the electron transport layer 10.

The display panel is placed on a spin coater, 100 μL-150 μL of photoresist is dropwise added onto the first electrodes 101, and the display panel rotates at a rotating speed in a range of 500 rpm-4000 rpm so as to coat on the first electrodes 101 with a photoresist layer. Then, the display panel is heated in an environment at the temperature of 50° C.-200° C., so that the photoresist becomes a film.

(4) The photoresist layer 30 is patterned.

Specifically, the photoresist layer 30 is patterned in exposure using mask. Specifically, the pattern of an exposure machine and the pattern of the display panel are aligned and adjusted, so that a mask shields regions outside the red sub-pixel regions, and mask exposure is performed on the red sub-pixel regions.

(5) The photoresist of the red sub-pixel regions 40 is removed.

Specifically, the exposed display panel is placed in alkali liquor with the mass fraction of 5%, such as a tetramethylammonium hydroxide aqueous solution or ammonia water, is soaked for 30-300 s, and then is washed with deionized water and blow-dried.

(6) Red quantum dot light emitting layers are formed in the red sub-pixel regions 40.

Specifically, a low-boiling-point solution of a red quantum dot material, such as an n-hexane or n-octane solution of the red quantum dot material, spin-coats on the display panel, and is dried at the temperature of 80° C.-120° C. to form a film.

(7) The whole display panel is fully exposed by adopting the exposure machine.

(8) The fully exposed display panel is placed in a developing solution with the mass fraction of 5%, such as a tetramethylammonium hydroxide aqueous solution or ammonia water, for 30-300 seconds, and then is washed with deionized water and blow-dried. In this way, red quantum dots are deposited in the red sub-pixel regions 40, and the red quantum dot materials on the green sub-pixel regions and the blue sub-pixel regions leave away from the display panel along with falling off of the photoresist.

As can be seen in FIG. 8, the electron transport layer 10 is provided with the pore structures, and the photoresist layer 30 is patterned to obtain red sub-pixel regions 40, as well as green sub-pixel regions and blue sub-pixel regions (FIG. 8 is illustrated with blank regions). The photoresist layer 30 in the red sub-pixel regions 40 is removed, then red quantum dot materials spin-coat the whole surface of the red sub-pixel regions 40, finally the photoresist layer 30 is washed off through a developing solution, so that the red quantum dot materials are deposited in the red sub-pixel regions 40, and the red quantum dot materials on the green sub-pixel regions and the blue sub-pixel regions leave away from the substrate 100 along with falling off of the photoresist. As in the red sub-pixel regions 40 in FIG. 8, shaded portions represents the red quantum dot materials, it can be seen from FIG. 8 that there is no red quantum dots in the green sub-pixel regions and the blue sub-pixel regions.

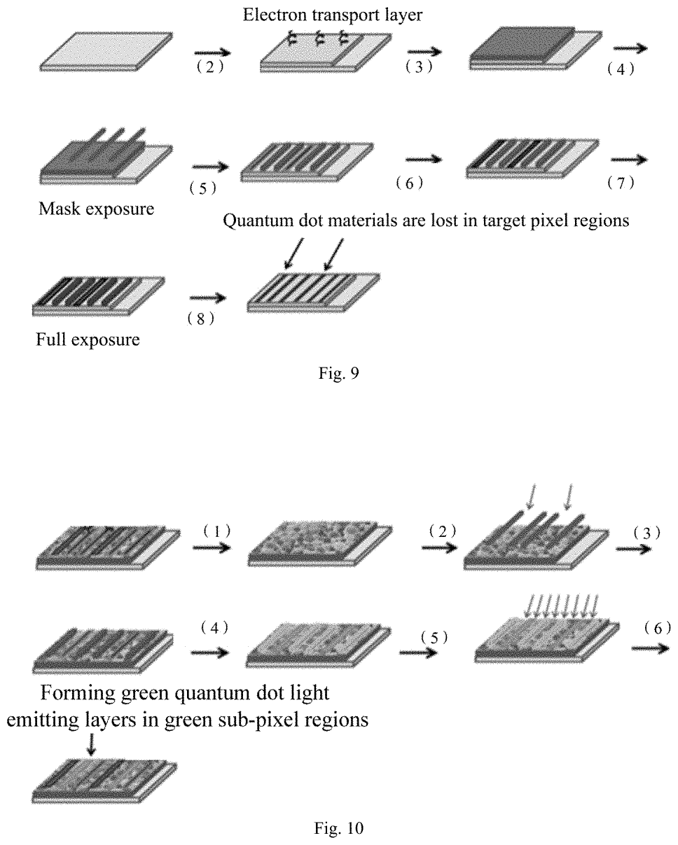

In the related art, the structure of the electron transport layer is loose, due to the fact that the binding force between the quantum dot materials and the photoresist layer is high through the step (3) to the step (8), and if the quantum dots on the photoresist are directly cleaned through the developing solution, then the quantum dot materials at the positions, without the photoresist (the electron transport layer), of the substrate are also washed off. The electron transport layer is loose in structure, when the quantum dots are washed off, the electron transport layer is likely to be washed off after being soaked in the developing solution, and the red quantum dots in the red sub-pixel regions are lost in the structure shown in FIG. 9. Curves on the electron transport layer after the step (2) in FIG. 9 represent chemical bonds of the electron transport layer, and the other ends may be connected with hydroxyl.

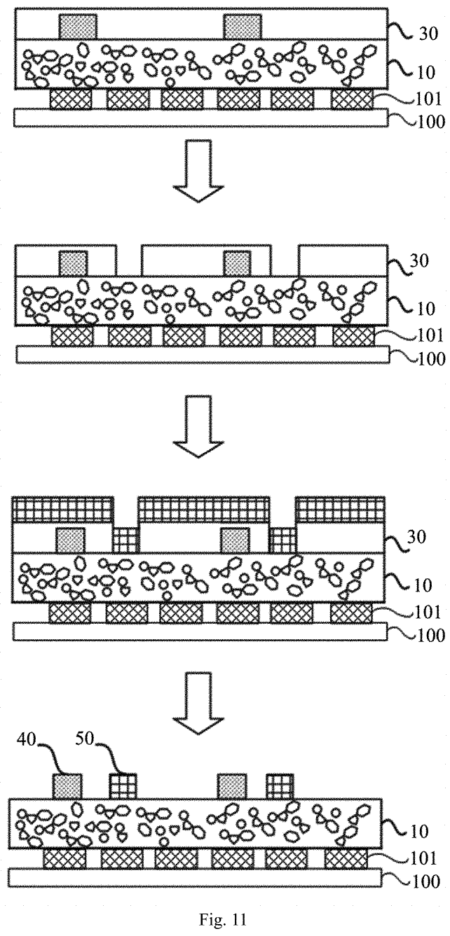

In the embodiment of the disclosure, after the red quantum dot light emitting layers are formed in the red sub-pixel regions, green quantum dot light emitting layers may be formed in the green sub-pixel regions by a similar method. Specifically, FIG. 10 is a flow diagram of forming green quantum dots in the green sub-pixel regions, FIG. 11 is a corresponding structure diagram of forming green quantum dot light emitting layers in the green sub-pixel regions, and as shown in FIG. 10 and FIG. 11, forming of the green quantum dots in the green sub-pixel regions includes the following steps.

(1) A photoresist 30 coats on a substrate 100 on which red quantum dots have been deposited.

A display panel with the deposited red quantum dot light emitting layers is placed on a spin coater, 100 μL-150 μL of photoresist is dropwise added onto the display panel, and the display panel rotates at a rotating speed in a range of 500 rpm-4000 rpm so as to coat the display panel with a layer of photoresist. Then, the display panel is heated in an environment at the temperature of 50° C.-200° C., so that a photoresist layer 30 is obtained.

(2) The photoresist layer 30 is patterned.

Specifically, the photoresist layer 30 is patterned in a mask exposure process. Specifically, patterns of an exposure machine and the display panel are aligned and adjusted, so that a mask shields regions outside the red sub-pixel regions, and mask exposure is performed on the green sub-pixel regions 50.

(3) The photoresist of the green sub-pixel regions 50 is removed.

Specifically, the exposed display panel is placed in a developing solution with the mass fraction of 5%, such as a tetramethylammonium hydroxide aqueous solution or ammonia water, is soaked for 30-300 seconds, and then is washed with deionized water and blow-dried.

(4) Green quantum dot light emitting layers are formed in the green sub-pixel regions 50.

Specifically, a low-boiling-point solution of a green quantum dot material, such as an n-hexane or n-octane solution of the green quantum dot material, is spin-coated on the display panel, and is dried at the temperature of 80° C.-120° C. to form a film.

(5) The whole display panel is fully exposed by adopting the exposure machine.

(6) The fully exposed display panel is placed in a developing solution with the mass fraction of 5%, such as a tetramethylammonium hydroxide aqueous solution or ammonia water, for 30-300 seconds, and then is washed with deionized water and blow-dried. In this way, green quantum dots are deposited in the green sub-pixel regions 50. Meanwhile, the photoresist in the red sub-pixel regions 40 falls off to expose the red quantum dots, and the green quantum dots in the blue sub-pixel regions leave away from the display panel along with falling off of the photoresist.

Similar to the principle of FIG. 8, shaded portions of the green sub-pixel regions 50 in FIG. 11 represent green quantum dot light emitting layers, blank regions represent blue sub-pixel regions and from FIG. 11, it can be seen that there is no green quantum dot light emitting layers in the blue sub-pixel regions.

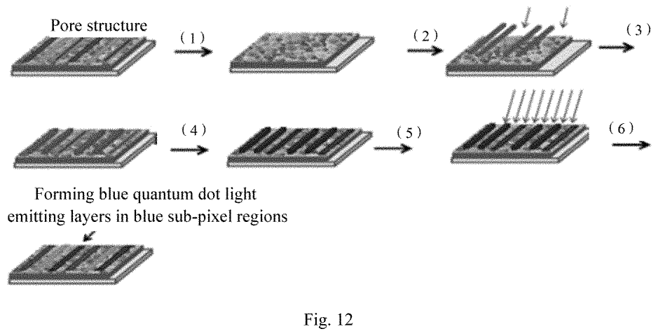

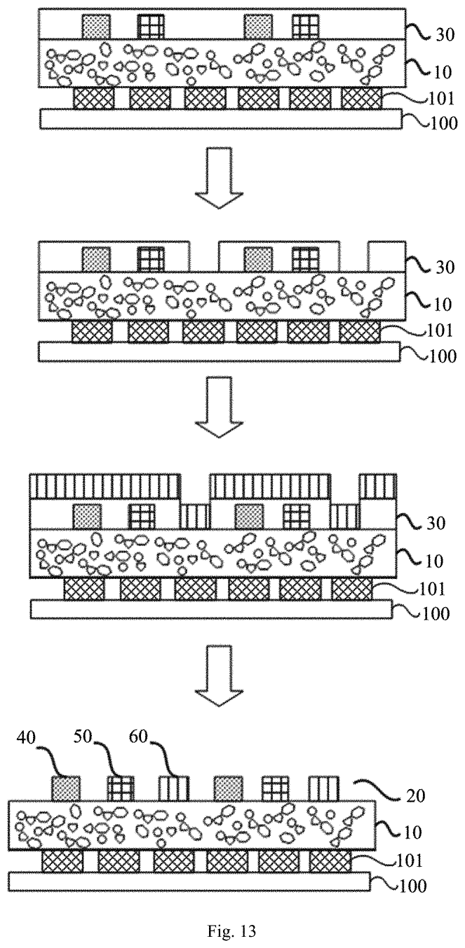

After the green quantum dot light emitting layers are formed in the green sub-pixel regions, blue quantum dot light emitting layers may be formed in the blue sub-pixel regions according to a similar method. Specifically, FIG. 12 is a flow diagram of forming the blue quantum dot light emitting layers in the blue sub-pixel regions, FIG. 13 is a corresponding structure diagram of forming the blue quantum dot light emitting layers in the blue sub-pixel regions, and forming of the blue quantum dot light emitting layers in the blue sub-pixel regions includes the following steps as shown in FIG. 12 and FIG. 13.

(1) A photoresist layer 30 is coated on the substrate 100 with the deposited red quantum dot light emitting layers and the deposited green quantum dot light emitting layers.

The display panel with the deposited red quantum dot light emitting layers and the deposited green quantum dot light emitting layers is placed on a spin coater, 100 μL-150 μL of photoresist is dropwise added onto the display panel, and the display panel rotates at a rotating speed in a range of 500 rpm-4000 rpm so as to coat the display panel with a layer of photoresist. Then, the display panel is heated in an environment at the temperature of 50° C.-200° C., so that the photoresist layer 30 is obtained.

(2) The photoresist layer 30 is patterned.

Specifically, the photoresist layer is patterned by adopting a mask exposure process. For example, patterns of an exposure machine and the display panel are aligned and adjusted, so that a mask shields regions outside the red sub-pixel regions, and mask exposure is performed on the blue sub-pixel regions 60.

(3) The photoresist of the blue sub-pixel regions 60 is removed.

Specifically, the exposed display panel is placed in a developing solution with the mass fraction of 5%, such as a tetramethylammonium hydroxide aqueous solution or ammonia water, is soaked for 30-300 seconds, and then is washed with deionized water and blow-dried.

(4) The blue quantum dot light emitting layers are formed in the blue sub-pixel regions 60.

Specifically, a low-boiling-point solution of a blue quantum dot material, such as an n-hexane or n-octane solution of the blue quantum dot material, is spin-coated on the display panel, and is dried at the temperature of 80° C.-120° C. to form a film.

(5) The whole display panel is fully exposed by the exposure machine.

(6) The fully exposed display panel is placed in a developing solution with the mass fraction of 5%, such as a tetramethylammonium hydroxide aqueous solution or ammonia water, for 30-300 seconds, and then is washed with deionized water and blow-dried. In this way, blue quantum dots are deposited in the blue sub-pixel regions. Meanwhile, the photoresist in the red sub-pixel regions falls off to expose the red quantum dot light emitting layers, and the photoresist in the green sub-pixel regions falls off to expose the green quantum dot light emitting layers.

Similar to the principle of FIG. 8, shaded portions of the blue sub-pixel regions 60 in FIG. 13 represent blue quantum dot light emitting layers, and it can be seen from FIG. 13 that the red sub-pixel regions 40 have red quantum dot light emitting layers, the green sub-pixel regions 50 have green quantum dot light emitting layers, the blue sub-pixel regions 60 have blue quantum dot light emitting layers, and thus, quantum dot light emitting layers 20 are obtained.

In practical application, in the manufacturing method according to the embodiment of the disclosure, referring to FIG. 2, after the step S503 and before the step S504, the following steps may further be performed. The hole transport layer 70 is formed on the quantum dot light emitting layers 20; and the hole injection layer 80 is formed on the hole transport layer 70.

Specifically, an organic substance, such as TFB (poly (9, 9-dioctylfluorene-CO—N-(4-butylphenyl) diphenylamine)), PVK (polyvinylcarbazole), or a triarylamine, is spin-coated on the quantum dot light emitting layers 20 to form the hole transport layer. Alternatively, an inorganic substance such as NiO and WO₃ is spin-coated on the quantum dot light emitting layers 20 to form the hole transport layer, and is dried to form a film. The PEDOT: PSS (poly 3, 4-ethylenedioxythiophene/polystyrene sulfonate) and the like is spin-coated on the hole transport layer to form the hole injection layer, and is dried to form a film.

Specifically, in the step S504, a second electrode 90 may be formed on the hole injection layer 80 by depositing an Al film or sputtering an IZO film. Then, an encapsulation cover plate covers the device, and the device is encapsulated by adopting ultraviolet curing adhesive under excitation of ultraviolet light and the like.

In conclusion, in the embodiment of the disclosure, the electron transport layer is provided with the plurality of pore structures, and compared with an electron transport layer with a relatively loose structure, the electron transport layer is not likely to be washed off by a developing solution when the quantum dot layer is patterned, so that the quantum dot light emitting layers on the electron transport layer are not likely to be washed off, and when the quantum dot light emitting layers are patterned, the yield of the quantum dot light emitting layers is improved. The electron transport layer is in direct contact with the quantum dot light emitting layers, so that the contact area between quantum dots in the quantum dot light emitting layers and the electron transport layer may be increased, more quantum dots are bound by the electron transport layer, and the light emitting effect of the light emitting layer of the display panel is enhanced.

It will be apparent to those skilled in the art that various modifications and variations may be made to the present disclosure without departing from the spirit and scope of the disclosure. Thus, it is intended that the present disclosure also encompass such modifications and variations as fall within the scope of the claims and their equivalents.

1. A display panel, comprising:
a base substrate;
first electrodes on the base substrate;
an electron transport layer on a side of the first electrodes away from the base substrate, wherein the electron transport layer is provided with a plurality of pore structures;
quantum dot light emitting layers on a side of the electron transport layer away from the base substrate, wherein the electron transport layer is in direct contact with the quantum dot light emitting layers; and
a second electrode on a side of the quantum dot light emitting layers away from the base substrate.

2. The display panel according to claim 1, wherein diameters of the pore structures of the electron transport layer are within a range [5 nm, 100 nm].

3. The display panel according to claim 1, wherein a material of the electron transport layer comprises metallic oxide.

4. The display panel according to claim 1, wherein a surface of the electron transport layer is provided with a hydrophilic ligand.

5. The display panel according to claim 1, further comprising a hole transport layer between the quantum dot light emitting layers and the second electrode, and a hole injection layer between the hole transport layer and the second electrode.

6. A display device, comprising the display panel according to claim 1.

7. A manufacturing method of the display panel according to claim 1, comprising:
forming first electrodes on a base substrate;
forming an electron transport layer with a plurality of pore structures on the first electrodes;
forming quantum dot light emitting layers on the electron transport layer, wherein the electron transport layer is in direct contact with the quantum dot light emitting layers; and
forming a second electrode on the quantum dot light emitting layers.

8. The manufacturing method according to claim 7, wherein said forming the electron transport layer with the plurality of pore structures on the first electrodes comprises:
preparing a zinc precursor solution by using a compound containing zinc ions;
forming a thin film on the first electrodes by using the zinc precursor solution; and
heating the display panel to enable the compound containing the zinc ions in the zinc precursor solution to be decomposed to generate gas and form the electron transport layer with the plurality of pore structures.

9. The manufacturing method according to claim 8, wherein said preparing the zinc precursor solution by using the compound containing the zinc ions comprises:
preparing a mixed solution of a dispersant and an organic solvent, wherein a boiling point of the dispersant is different from a boiling point of the organic solvent;
adding the compound containing the zinc ions to the mixed solution; and
heating and stirring the mixed solution with the compound containing the zinc ions to form the zinc precursor solution.

10. The manufacturing method according to claim 9, wherein an amount of the dispersant is within a range [1 ml, 8 ml].

11. The manufacturing method according to claim 8, wherein said heating the display panel comprises:
heating the display panel in an environment in a first temperature range for a first duration; wherein the first temperature range is [80° C., 150° C.], and the first duration is within a range [5 min, 10 min].

12. The manufacturing method according to claim 11, wherein said heating the display panel comprises:
heating the display panel in a temperature range [80° C., 100° C.] for [5 min, 7 min]; and
heating the display panel in a temperature range [120° C., 150° C.] for [8 min, 10 min].

13. The manufacturing method according to claim 11, wherein after heating the display panel in the environment in the first temperature range for the first duration, the manufacturing method further comprises:
heating the display panel in an environment in a second temperature range for a second duration; wherein the second temperature range is [200° C., 300° C.], and the second duration is within a range [3 min, 10 min].

14. The manufacturing method according to claim 8, wherein after heating the display panel, the manufacturing method further comprises:
coating an aqueous solution containing a binder on a surface of the electron transport layer; and
heating the display panel in a third temperature range for a third duration to obtain the electron transport layer of which the surface is provided with a hydrophilic ligand.

15. The manufacturing method according to claim 7, wherein the display panel comprises sub-pixels in at least three colors;
said forming the quantum dot light emitting layers on the electron transport layer comprises:
forming the quantum dot light emitting layers in corresponding colors in sub-pixel regions in different colors; wherein
for the sub-pixel regions in each color, said forming the quantum dot light emitting layers in the corresponding color comprises:
coating a photoresist layer on the electron transport layer, and patterning the photoresist layer to remove the photoresist layer in the sub-pixel regions in the color;
spin-coating quantum dot materials in the color on a whole surface of the photoresist layer; and
stripping off the photoresist layer to remove the quantum dot materials on the photoresist layer, and forming the quantum dot light emitting layers in the sub-pixel regions in the color.

16. The manufacturing method according to claim 15, wherein after forming the quantum dot light emitting layers on the electron transport layer and before forming the second electrode on the quantum dot light emitting layers, the manufacturing method further comprises:
forming a hole transport layer on the quantum dot light emitting layers; and
forming a hole injection layer on the hole transport layer.
